(19) United States
(12) Patent Application Publication
(10) Pub. No.: US 2005/0212131 A1
(43) Pub. Date: Sep. 29, 2005

(54) Electric wave readable data carrier manufacturing method, substrate, and electronic component module

(76) Inventor: Wakahiro Kawai, Kyoto (JP)

Correspondence Address: DICKSTEIN SHAPIRO MORIN & OSHINSKY LLP, 2101 L Street, NW, Washington, DC, 20037, US

(21) Appl. No.: 11/088,990

(22) Filed: Mar. 24, 2005

(30) Foreign Application Priority Data
Mar. 24, 2004 (JP) P. 2004-088073

(51) Int. Cl. H01L 29/40

(52) U.S. Cl. 257/737

(57) ABSTRACT

The method for mounting the IC chip on the substrate comprises: pushing bumps of the semiconductor bare chip onto the thermoplastic resin film while applying an ultrasonic wave thereto, thereby to expel the thermoplastic resin film to bring the bumps and the electrode areas into contact; further applying the ultrasonic wave continuously while the bumps and the electrode areas contacting, thereby to join the bumps and the electrode areas ultrasonically; and cooling and solidifying the thermoplastic resin film thereby to adhere the semiconductor bare chip body to the substrate. The method can manufacture the electric wave readable data carrier efficiently.

This application claims foreign priority based on Japanese patent application JP 2004-088073, filed on Mar. 24, 2004, the contents of which is incorporated herein by reference in its entirety.

### BACKGROUND OF THE INVENTION

1. Field of the Invention

The present invention relates to a method for mounting a semiconductor chip suitable for an electric wave readable data carrier to function as an flight tag, a physical distribution managing label or the like and to use electric waves of a UHF band (e.g., 850 MHz or higher, preferably 850 to 960 MHz) as a communication frequency, and to a method for manufacturing the electric wave readable data carrier capable of elongating the communication distance, and a substrate for use in the manufacturing method.

2. Description of the Related Art

In order to develop automations of the physical distribution, it is important that the contents of tags to be adhered to individual articles or the like can be read by a machine. For this purpose, in the related art, bar code labels corresponding to the contents of individual tags are adhered to the tags.

In order to read the bar code labels with the so-called “bar code reader”, however, the correlations of predetermined distances and directions have to be highly precisely made between them, thus causing troubles to the smooth physical distribution. In addition, the quantity of information to be inputted to the bar codes is little, and the management range of the physical distribution is limited within a narrow range.

In recent years, therefore, there have been used the tag built-in type IC labels which can be read non-contact by using the induction field. According to these tag built-in type IC labels, the induction field is used as a reading medium so that the reading operation is restricted in neither distance nor direction so that the contents can be reliably read out.

Moreover, the IC in the IC label can store a large capacity of the personal information of the article to be managed, and the personal information storing function can also be used as the security information for specifying the individuals.

However, the readable distance (as will be called the “reading distance”) by this method using the induction field is about 50 cm, and there increase applications, for which that short reading distance is insufficient. As means for solving the problem of the short reading distance, therefore, there has been investigated the method for acquiring a reading distance of 3 to 5 m by utilizing the electric waves of the UHF band (850 to 960 MHz). A configuration of the IC label using the electric waves of the UHF band is described with reference to FIG. 10.

FIG. 10(a) is a top plan view showing a configuration of the IC label of the related art, as used in the UHF frequency band, and FIG. 10(b) is a sectional view showing the configuration of the IC label of FIG. 10(a), as cut in the direction of the longitudinal axis. As shown at (a) and (b) in FIG. 10, an IC label 10 includes an IC chip 11 having a memory function therein, an antenna 12, and a substrate 13 having a circuit pattern.

Usually in the IC labels used in this frequency band, in order to elongate the reading distance, the impedance Z_{Chip} owned by the IC chip 11 forming the IC label and the impedance Z_{Antenna} owned by the antenna 12 have to match each other thereby to maximize the power to be transmitted/received from the IC label 10 to the lead antenna.

Specifically, it is known that the impedance Z_{Antenna} of the antenna 12 is generally higher than the impedance Z_{Chip} of the IC chip 11 determined by the internal circuit configuration. In order that the impedance Z_{Chip} of the IC chip 11 and the impedance Z_{Antenna} of the antenna 12 may match each other to maximize the power to be transmitted/received from the IC label 10 to the lead antenna, therefore, the impedance Z_{Antenna} has to be designed to a small value by attaching a loading bar to the antenna 12, for example.

When the IC chip 11 is mounted on the circuit pattern, on the other hand, the impedance Z_{Chip} is made lower according to the following general equation (1) by a condenser component C inserted between the IC chip 11 and the circuit pattern. This makes it substantially necessary to make such a design that the impedance Z_{Antenna} of the antenna 12 matches the impedance Zp of the case, in which the IC chip 11 is mounted on the circuit. As the condenser component C at the time the IC chip 11 is mounted increases, however, there arises a problem that the antenna 12 has to have a more complex shape. When the antenna 12 dispersed in shape, moreover, there arises another problem that the communication characteristics of the IC label 10 become liable to fluctuate.
Impedance:Z=R−j(1/ωC)Ω (1)
(ω=communication frequency f/2π,
R: a value inversely proportional to the magnitude C)

Next, FIG. 11 shows an IC chip mounting method with an anisotropic conductive material (an anisotropic conductive film (ACF) and an anisotropic conductive paste (ACP)). This mounting method is disclosed in Japanese Patent No. 2,586,154 (JP-A-3-29207 (Laid-Open Date: Feb. 7, 1991)), for example. In this mounting method, an anisotropic conductor material 20 containing conductor particles 22 dispersed in a thermoplastic or thermoset resin binder 21 is inserted between the IC chip 11 and a circuit pattern 23, and the resin is made to flow by a thermocompression so that an electric connection in the thickness direction (i.e., between the bumps 24 and the circuit pattern 23) may be acquired by the conductive particles 22 sandwiched between the electrode portions (as will be called the “bumps 24”) of the IC chip and the circuit pattern 23.

This method can make relatively rough the alignment with the circuit pattern 23 of the substrate at the time when the IC chip 11 is mounted and has a resin setting time as short as 10 to 20 seconds but need not use an encapsulating agent such as an under-fill, so that it can aim at lowering the manufacturing cost. Thus, the method is widely used as one for manufacturing the IC labels.

As seen from equivalent circuits shown in FIG. 11, however, a number of condensers having the resin binder 21 as the dielectric material and the conductive particles 22 as the electrode are formed between the IC chip 11 and the circuit pattern 23. This configuration is like that, in which a large capacitor is formed to have those numerous capacitors connected in parallel. As a result, the impedance Zp is reduced to raise a problem that the antenna 12 has to be large-sized.

As a method for solving this problem of the large-sized antenna, there has been adopted a method, in which the circuit pattern 23 is formed in the mode shown in FIG. 12 to reduce the capacitor component C. Specifically, there is adopted a method, in which only two 24 and 24 of the four shown bumps 24 are electrically connected with the circuit pattern 23.

In case the condenser component C is to be reduced by the aforementioned method, however, a highly precise alignment between the IC chip 11 and the circuit pattern 23 is needed to raise a problem that the manufacturing cost rises. Moreover, the level balance of the lower portion of the IC chip 11 is so poor as to raise a problem that the reliability in the connection between the bumps 24 or the electrodes of the IC chip and the circuit pattern 23 is degraded.

On the other hand, there can be conceived a method, in which the IC chip 11 is mounted only by the adhesive resin binder 21 excepting the conductive particles 22 from the anisotropic conductor material 20, thereby to reduce the condenser component C. However, this method leaves such a problem unsolved that the reliability in the connection between the bumps 24 of the IC chip 11 and the circuit pattern 23 is degraded.

Therefore, there has been earnestly desired the development of an IC chip mounting method which can reduce the condenser component C of the IC chip in the IC label using the electric waves of the UHF band and which has a high reliability for mounting the IC chip.

### SUMMARY OF THE INVENTION

The invention has been conceived in view of the problems thus far described. It is an object to provided a method for manufacturing an electric wave readable data carrier using an electric wave of 850 MHz (e.g., the UHF band) or higher as a communication frequency. The method can reduce a condenser capacity to be made when an IC chip is mounted on a conductor pattern, to a small value and can mount the IC chip highly reliably at a low cost. The invention has another object to provide a substrate and an electronic component module to be used in the manufacturing method.

In order to solve the aforementioned problems, according to the invention, there is provided a method for manufacturing an electric wave readable data carrier having a semiconductor bare chip with a bump mounted on a substrate and using an electric wave of 850 MHz or higher as a communication frequency, wherein the substrate includes a conductor pattern for forming an antenna, and a thermoplastic resin film for covering an electrode area on the conductor pattern. The method for mounting a semiconductor bare chip on the substrate comprises: the step of pushing the bump of the semiconductor bare chip onto the thermoplastic resin film while applying an ultrasonic wave thereto, thereby to expel the thermoplastic resin film to bring the bump and the electrode area into contact; the step of further applying the ultrasonic wave continuously while the bump and the electrode area contacting, thereby to join the bump and the electrode area ultrasonically; and the step of cooling and solidifying the thermoplastic resin film thereby to adhere the semiconductor bare chip to the substrate.

According to the aforementioned configuration, no conductive particle exists between the semiconductor bare chip and the conductor pattern (e.g., the wiring pattern or the circuit pattern) so that the formation of the condenser component between the semiconductor bare chip and the conductor pattern can be reduced. Moreover, the electrodes (or the bumps) of the semiconductor bare chip and the conductor pattern are connected by the metal fusion so that a highly reliable semiconductor chip can be mounted with a high reliability in the electric connection and with a high mechanical strength.

Moreover, the mounting time by the ultrasonic waves is about 2 seconds so that the productivity can be improved to lower the manufacturing cost. In addition, the formation of the capacitor component can be suppressed to make it unnecessary to extremely reduce the area of the circuit pattern on the lower face side of the semiconductor bare chip thereby not to require highly precise alignment but to stabilize the mounted state of the semiconductor chip.

Moreover, the insulating particles having a high dielectric constant are absent between the semiconductor bare chip and the conductor pattern. This absence results in an advantage that the condenser capacity can be reduced.

Therefore, it is possible to efficiently manufacture an electric wave readable data carrier which uses electric waves of 850 MHz or higher (e.g., the UHF band) as the communication frequency. These advantages make it possible to massively manufacture the electromagnetic wave readable data carriers of high performances, which can function as the flight tag, the physical distribution management label, the unattended wicket pass and so on.

Here, the “substrate” is preferably a film-shaped, sheet-shaped or thin-plate-shaped insulating substrate.

In order to solve the aforementioned problems, according to the invention, there is provided a method for manufacturing an electric wave readable data carrier having a semiconductor bare chip with a bump mounted on a substrate and using an electric wave of 850 MHz or higher as a communication frequency, wherein the substrate includes a conductor pattern for forming an antenna, a resin film containing insulating particles dispersed therein for covering an electrode area on the conductor pattern, and a thermoplastic resin film for covering the resin film containing the dispersed insulating particles. The method for mounting a semiconductor bare chip on the substrate comprises: the step of pushing the bump of the semiconductor bare chip onto the thermoplastic resin film while applying an ultrasonic wave thereto, thereby to expel the thermoplastic resin film to bring the bump to the surface of the resin film containing the dispersed insulating particles; the step of pushing the bump onto the resin film containing the dispersed insulating particles by further applying the ultrasonic wave continuously, thereby to expel the resin film while releasing the insulating particles from the inside of the resin film, to bring the bump and the electrode area into contact; the step of further applying the ultrasonic wave continuously while the bump and the electrode area contacting, thereby to join the bump and the electrode area ultrasonically; and the step of cooling and solidifying the thermoplastic resin film thereby to adhere the semiconductor bare chip to the substrate.

According to the aforementioned configuration, no conductive particle exists between the semiconductor bare chip and the conductor pattern (e.g., the wiring pattern or the circuit pattern) so that the formation of the condenser component between the semiconductor bare chip and the conductor pattern can be reduced. Moreover, the electrodes (or the bumps) of the semiconductor bare chip and the conductor pattern are connected by the metal fusion so that a highly reliable semiconductor chip can be mounted with a high reliability in the electric connection and with a high mechanical strength.

Moreover, the mounting time by the ultrasonic waves is about 2 seconds so that the productivity can be improved to lower the manufacturing cost. In addition, the formation of the capacitor component can be suppressed to make it unnecessary to extremely reduce the area of the circuit pattern on the lower face side of the semiconductor bare chip thereby not to require highly precise alignment but to stabilize the mounted state of the semiconductor chip.

According to the aforementioned manufacturing method, moreover, the resin film layer containing the insulating particles of a high dielectric constant exists between the semiconductor bare chip and the conductor pattern. Unlike the case, in which only the thermoset resin is present between the semiconductor bare chip and the conductor pattern, it is possible to solve the problem that the electric insulation between the semiconductor bare chip and the conductor pattern cannot be held under the condition of a high temperature applied. Specifically, the resin film containing the insulating particles is interposed between the semiconductor bare chip and the electrode areas (or the wiring pattern). Even a high temperature and a high-pressure load are applied to the mounting portion of the semiconductor bare chip, therefore, the situation, in which the semiconductor bare chip and the wiring pattern make direct contact, can be prevented in advance by the presence of the resin film. It is, therefore, possible to realize the highly reliable data carrier having no fear of such short-circuit. Therefore, the aforementioned advantages make it possible to massively manufacture the electromagnetic wave readable data carriers of high performances, which can function as the flight tag, the physical distribution management label, the unattended wicket pass and so on.

Especially, because of the presence of the resin film containing the insulating particles dispersed therein, the step of for the resin film to insert the bumps into the resin film can be simplified by pushing the bumps onto the resin film while applying the ultrasonic vibrations thereto. Supposing that the insulating film (or the insulating layer) is interposed between the thermoplastic resin film and the wiring pattern, for example, the bumps cannot easily pass, even if ultrasonically vibrated, into (or partially remove) the insulating layer. In the invention, on the contrary, the bumps are ultrasonically vibrated to bring the insulating particles from the resin film so that the resin layer is pored to become brittle in resistance. Therefore, the bumps can easily dig into the resin film for a short time period thereby to bring their leading end portions to the electrode areas.

Therefore, it is possible to efficiently manufacture an electric wave readable data carrier which uses electric waves of 850 MHz or higher (e.g., the UHF band) as the communication frequency.

As apparent from the foregoing steps, the resin film containing the insulating particles dispersed in advance is formed at the electrode areas on the conductor pattern of the substrate to be used in the invention. Moreover, the thermoplastic resin film is formed on that resin film. The resin film containing the insulating particles dispersed therein may cover only the electrode areas of the conductor pattern or wholly the conductor pattern surface.

Herein, the phrase “electrode areas” means predetermined small areas on the conductor pattern including the positions, which are scheduled to be connected with the terminals or the like of the electronic components. Those electrode areas will contain the portions, as generally called the “lands”, on the conductor pattern.

As “contained and dispersed”, it is preferred that the insulating particles are homogeneously dispersed in the resin film. These insulating particles are contained to produce the pores in the resin film when the insulating particles are removed from the resin film by the ultrasonic vibrations of the bumps. When the pores are formed in the resin film, this resin film becomes brittle in resistance so that the bumps can be easily inserted into the resin film. Despite of the “contained and dispersed”, however, the insulating particles need not homogeneously exist in the entire region in the resin film, but it seems sufficient that a predetermined amount of insulating particles are present at least in the vicinity of the electrode areas (that is, in the vicinity of the resin film, into which the bumps are to be inserted).

Here, the phrase “while releasing the insulating particles from the inside of the resin film) means both the cases, in which the insulating particles are completely released from the resin film, and in which the insulating particles are partially protruded from the resin film.

Here, the “substrate” is preferred to be an insulating substrate having a film shape, a sheet shape or a thin plate shape.

In the electric wave readable data carrier manufacturing method according to the invention, it is preferred that the insulating particles contained and dispersed in the resin film are insulating particles having a dielectric constant of 3 or less. According to this configuration, it is possible to ensure the electric insulation between the semiconductor bare chip and the conductor pattern.

As the material for the “insulating particles” in the invention, there can be enumerated silicon oxides, super-hydrophobic silicon oxides, aluminum oxides or tetrafluoroethylene. It seems from the viewpoint of the pressure resistance that inorganic oxides having a relatively high hardness such as the silicon oxides, the super-hydrophobic silicon oxides and the aluminum oxides are preferable. Nevertheless, the aluminum oxides have a relatively high dielectric constant so that the silicon oxides are preferred for the applications, in which the condenser component is extremely avoided just below the semiconductor bare chip. In case it is necessary to cut the wiring substrate according to an application, the content of the hard particles such as the silicon oxide particles or the aluminum oxide particles in the resin film may shorten the lifetime of the cutting blade. In this case, it seems preferable to use the relatively soft tetrafluoroethylene.

In the invention, moreover, it is preferred that the content of the insulating particles contained and dispersed in the resin film is 10 wt. % to 30 wt. % of 100 wt. % of the resin. This fact has been found out as a result of the keen investigations. At less than 10 wt. %, it has been confirmed difficult for the bumps to dig into the resin film (that is, to make the electric connections between the semiconductor bare chip and the electrode areas). At more 30 wt. %, on the other hand, it has been confirmed that the workability of the resin is degraded.

It has also been found preferable in the invention that the diameter of the insulating particles contained and dispersed in the resin film is 70% or more of the thickness of the resin film. This is needless to say. As the diameter of the insulating particles becomes the larger, the pores in the resin, as formed when the insulating particles go out of the resin film, become accordingly the larger to make the insertions of the bumps easier.

In the invention, moreover, it is preferred that the resin film containing the dispersed insulating particles is made of a thermoset resin. The thermoset resin film, which is not melted at a high temperature, resides between the semiconductor bare chip and the electrode areas (i.e., the wiring pattern). Even if the high temperature and the high-pressure load are applied to the package of the semiconductor bare chip, the semiconductor bare chip and the wiring pattern can be reliably prevented from directly contacting with each other by the presence of the thermoset resin film.

Therefore, a similar effect can be obtained, when the resin film containing the dispersed insulating particles is made of a thermoplastic resin having a higher re-softening temperature than that of the material of the thermoplastic resin film covering the resin film.

Here, the invention can contain the substrate which can also be used in the aforementioned data carrier manufacturing method.

That is, a substrate to be used in the aforementioned electric wave readable data carrier manufacturing method, comprises: a conductor pattern for forming an antenna; a resin film covering an electrode area on the conductor pattern and containing insulating particles dispersed therein; and a thermoplastic resin film covering the resin film containing the dispersed insulating particles, wherein the insulating particles contained and dispersed in the resin film are silicon oxides or super-hydrophobic silicon oxides.

A substrate to be used in the aforementioned electric wave readable data carrier manufacturing method comprises: a conductor pattern for forming an antenna; a resin film covering an electrode area on the conductor pattern and containing insulating particles dispersed therein; and a thermoplastic resin film covering the resin film containing the dispersed insulating particles, and the insulating particles contained and dispersed in the resin film are tetrafluoroethylene.

A substrate to be used in the aforementioned electric wave readable data carrier manufacturing method comprises: a conductor pattern for forming an antenna; a resin film covering an electrode area on the conductor pattern and containing insulating particles dispersed therein; and a thermoplastic resin film covering the resin film containing the dispersed insulating particles, and the insulating particles contained and dispersed in the resin film are particles having a diameter of 70% or more of the thickness of the resin film.

A substrate to be used in the aforementioned electric wave readable data carrier manufacturing method comprises: a conductor pattern for forming an antenna; a resin film covering an electrode area on the conductor pattern and -containing insulating particles dispersed therein; and a thermoplastic resin film covering the resin film containing the dispersed insulating particles, and the content of the insulating particles contained and dispersed in the resin film is from 10 wt. % to 30 wt. % of 100 wt. % of the resin.

A substrate to be used in the aforementioned electric wave readable data carrier manufacturing method comprises: a conductor pattern for forming an antenna; a resin film covering an electrode area on the conductor pattern and containing insulating particles dispersed therein; and a thermoplastic resin film covering the resin film containing the dispersed insulating particles, and the resin film containing the dispersed insulating particles is made of a thermoset resin.

A substrate to be used in the aforementioned electric wave readable data carrier manufacturing method comprises: a conductor pattern for forming an antenna; a resin film covering an electrode area on the conductor pattern and containing insulating particles dispersed therein; and a thermoplastic resin film covering the resin film containing the dispersed insulating particles, and the resin film containing the dispersed insulating particles is a thermoplastic resin having a higher re-softening temperature than that of the material of the thermoplastic resin film covering the resin film.

In the aforementioned individual substrates, moreover, it is preferred that the insulating particles contained and dispersed in the resin film are insulating particles having a dielectric constant of 3 or less.

By using the substrate thus configured, the semiconductor bare chip can be easily mounted on the wiring substrate by the ultrasonic mounting method merely by disposing the predetermined bumps on the semiconductor bare chip. Then, it is possible to provide the satisfactory data carrier having the aforementioned excellent advantages.

In order to solve the aforementioned problems, according to the invention, there is provided a method for manufacturing an electric wave readable data carrier using an electric wave of 850 MHz or higher as a communication frequency and comprising a data carrier body and an electronic component module, the data carrier body including a conductor pattern forming an antenna formed on an insulating substrate, the electronic component module including a wiring substrate having a wiring pattern and a thermoplastic resin film covering an electrode area on the wiring pattern, and a semiconductor bare chip with a bump. The method for manufacturing the electronic component module comprises: the step of pushing the bump of the semiconductor bare chip onto the thermoplastic resin film while applying an ultrasonic wave thereto, thereby to expel the thermoplastic resin film to-bring the bump and the electrode area into contact; the step of further applying the ultrasonic wave continuously while the bump and the electrode area contacting, thereby to join the bump and the electrode area ultrasonically; and the step of cooling and solidifying the thermoplastic resin film thereby to adhere the semiconductor bare chip body to the wiring substrate.

In order to solve the aforementioned problems, according to the invention, there is provided a method for manufacturing an electric wave readable data carrier using an electric wave of 850 MHz or higher as a communication frequency and comprising a data carrier body and an electronic component module, the data carrier body including a conductor pattern forming an antenna formed on an insulating substrate, the electronic component module including a wiring substrate having a wiring pattern, a resin film containing insulating particles dispersed therein for covering an electrode area on the wiring pattern and a thermoplastic resin film covering the resin film containing the dispersed insulating particles, and a semiconductor bare chip with a bump. The method for manufacturing the electronic component module comprises: the step of pushing the bump of the semiconductor bare chip onto the thermoplastic resin film while applying an ultrasonic wave thereto, thereby to expel the thermoplastic resin film to bring the bump to the surface of the resin film containing the dispersed insulating particles; the step of pushing the bump onto the resin film containing the dispersed insulating particles by further applying the ultrasonic wave continuously, thereby to expel the resin film while releasing the insulating particles from the inside of the resin film, to bring the bump and the electrode area into contact; the step of further applying the ultrasonic wave continuously while the bump and the electrode area contacting, thereby to join the bump and the electrode area ultrasonically; and the step of cooling and solidifying the thermoplastic resin film thereby to adhere the semiconductor bare chip body to the wiring substrate.

According to the configurations thus far described, it is needless to say that the aforementioned advantages can be achieved. The semiconductor bare chip is mounted not directly on the large-sized conductor pattern (to form the antenna) but on the small-sized module substrate. This results in an advantage that the mounting precision of the semiconductor chip can be better improved.

Here, the phrase “electronic component module” is preferably the electronic component module which is prepared by mounting the semiconductor chip for forming the transmitter/receiver circuit, the memory and the like on the wiring pattern of the film-shaped resin substrate surface.

In the electric wave readable data carrier manufacturing method according to the invention, it is preferred in the electronic component module that the wiring substrate to confront the semiconductor bare chip is formed excepting areas other than an area where the bump of the semiconductor bare chip and the wiring substrate contact.

According to the aforementioned configuration, the area of the wiring substrate to confront the semiconductor bare chip can be reduced. As a result, it is possible to reduce the impedance Zp after the semiconductor bare chip was mounted on the data carrier body.

It is also preferred: that the electric wave readable data carrier manufacturing method further comprises, before the step of pushing the bump of the semiconductor bare chip while applying the ultrasonic wave thereto, the step of forming an adhesive layer in an area of the wiring substrate to confront said semiconductor bare chip excepting the area in which the bump of said semiconductor bare chip and the wiring substrate contact; and that the step of pushing the bump of the semiconductor bare chip while applying the ultrasonic wave thereto, includes the step of pushing with a load to compress and deform a portion of the wiring substrate.

In order to reduce the impedance Zp after the semiconductor bare chip was mounted on the data carrier body, the circuit portion just below the semiconductor bare chip in the wiring substrate to confront the semiconductor bare chip is partially removed. Therefore, the contact area between the semiconductor bare chip and the circuit portion is reduced. In this case, the junction strength (as will be called the “shared strength”) between the semiconductor bare chip and the wiring substrate is reduced to raise a problem that the mounting reliability of the semiconductor chip drops. However, this problem can be avoided according to the aforementioned configuration.

It is also preferred that a portion of the wiring substrate to be compressed and deformed in the wiring pattern.

In the invention, moreover, there is contained an electronic component module comprising: a wiring substrate including a wiring pattern and a thermoplastic resin film for covering an electrode area on the conductor pattern; and a semiconductor bare chip having a bump, wherein the semiconductor bare chip is mounted on the wiring substrate, and wherein, in the electronic component module, the wiring substrate to confront the semiconductor bare chip is formed excepting areas other than an area where the bump of the semiconductor bare chip and the wiring substrate contact.

In the invention, moreover, there is also contained an electronic component module comprising: a wiring substrate having a wiring pattern, a resin film containing insulating particles dispersed therein for covering an electrode area on the conductor pattern and a thermoplastic resin film covering the resin film containing the dispersed insulating particles; and a semiconductor bare chip having a bump, wherein the semiconductor bare chip is mounted on the wiring substrate, and wherein, in the electronic component module, the wiring substrate to confront the semiconductor bare chip is formed excepting areas other than an area where the bump of the semiconductor bare chip and the wiring substrate contact.

By using the aforementioned electronic component module, the aforementioned electric wave readable data carrier manufacturing method can be more conveniently executed.

According to the electric wave readable data carrier manufacturing method according to the invention, there is provided an electric wave readable data carrier which uses electric waves of 850 MHz or higher (e.g., the UHF band) as the communication frequency. This raises another advantage that the semiconductor bare chip can be quickly mounted electrically and electrically reliably mounted on the substrate at a low cost.

In case the resin film contains the insulating particles, moreover, even under the situations where the loads of a high temperature and a high pressure are applied to the package of the semiconductor bare chip, there can be achieved an advantage that it is possible to prevent the short-circuit from being caused by the contact between the semiconductor bare chip and the electrode area on the wiring substrate.

According to the invention, therefore, it is possible to massively manufacture the electromagnetic wave readable data carriers, which can function as the flight tag, the physical distribution management label, the unattended wicket pass and so on, at a low cost.

### BRIEF DESCRIPTION OF THE DRAWINGS

FIG. 1 is a diagram schematically showing a section of the structure of a package of the case, in which an IC chip is mounted on the substrate of the data carrier according to an embodiment.

FIG. 2(a) is a diagram schematically showing a step E at the time of mounting the IC chip on the data carrier according to the embodiment, FIG. 2(b) is a diagram schematically showing a step F at the time of mounting the IC chip on the data carrier according to the embodiment, and

FIG. 2(c) is a diagram schematically showing a step G at the time of mounting the IC chip on the data carrier according to the embodiment.

FIGS. 3(a) to 3(d) are diagrams schematically showing a step A to a step D or characteristic pre-steps of the data carrier manufacturing method of the embodiment before the steps E to G, and show the step A, the step B, the step C and the step D, respectively.

FIGS. 4(a) and 4(b) show the steps of mounting the IC chip of the case, in which the thermoset resin layer 44 having insulating particles dispersed therein is absent.

FIG. 5(a) is a top plan view showing an electric wave readable data carrier according to another embodiment of the invention, and FIG. 5(b) is a diagram showing a section of FIG. 5(b).

FIG. 6 is a diagram schematically showing a circuit pattern of a wiring substrate of an electronic component module according to another embodiment of the invention.

FIG. 7 is a diagram schematically showing a problem owned by the package of the IC chip shown in FIG. 6.

FIG. 8(a) and FIG. 8(b) are diagrams schematically showing the step A and the step B of a method for manufacturing the data carrier in another embodiment according to the invention.

FIG. 9 is a diagram showing the results of comparisons of individual shared strengths of the package of Embodiment 1, the package of FIG. 6 of Embodiment 2 and the package of this embodiment.

FIG. 10(a) is a top plan view showing a configuration of the IC label of the related art to be used for a UHF frequency band, and FIG. 10(b) is a sectional view showing the configuration of the section of the IC label of FIG. 10(b) and taken along the longitudinal axis.

FIG. 11 is a diagram showing an IC chip mounting method of the related art with an anisotropic conductive material.

FIG. 12 presents diagrams schematically showing circuit patterns as one example of the method of the related art for solving the problem of the large-sized antenna.

### DETAILED DESCRIPTION OF THE INVENTION

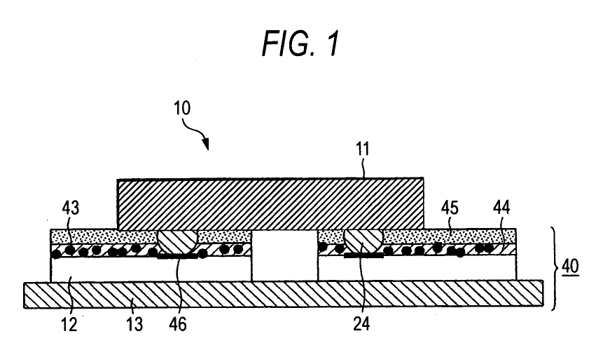

One embodiment of the invention is described in the following with reference to FIG. 1 to FIG. 4 and FIG. 10.

First of all, a fundamental structure of a data carrier 10 according to this embodiment for reading electronic waves is identical to that of the related art so that it is described with reference to FIG. 10. As shown in at (a) and (b) in FIG. 10, the data carrier 10 has a structure, in which a conductor pattern 12 made of hard aluminum of 35 microns for forming an antenna is formed on one face of a substrate 13 made of a film resin base material of PET (polyethylene terephthalate) of 38 microns and in which an IC chip 11 is mounted on one end of the conductor pattern 12. Here, the data carrier 10 can read electronic waves of 850 MHz or higher or preferably electronic waves of a UHF band of 850 MHz to 960 MHz as a communication frequency.

On the other hand, FIG. 1 schematically shows a section of the structure of a printed circuit board of the case, in which the IC chip is mounted on the substrate of the data carrier according to the embodiment. As shown in FIG. 1, the data carrier 10 is provided with the IC chip 11 and a wiring substrate 40. This wiring substrate 40 is provided with the substrate 13 made of the resin base material, the conductor pattern 12, a resin layer 44 containing dispersed insulating particles 43, and an adhesive layer 45.

The conductor pattern 12 is stacked on the substrate 13, and the surface of the conductor pattern 12 is covered with the resin layer 44 containing the dispersed insulating particles 43. Here, these insulating particles 43 are inorganic or resin particles and exemplified in this embodiment by silica (SiO₂) particles of 2 to 4 microns. Moreover, the resin layer 44 is made of an epoxy thermoset resin film having a thickness of 4 microns. On this resin layer 44, there is disposed the adhesive layer 45 which is made of a thermoplastic resin. This adhesive layer 45 is formed of a polyolefin thermoplastic resin film having a softening temperature of 90° C. to 100° C.

Moreover, the IC chip 11 is provided with electrodes (as will be called “bumps”) 24 protruding on the face confronting the wiring substrate 40. The bumps 24 of the IC chip 11 are electrically joined at junction portions (or metal fusion portions) 46 to the conductor pattern 12 through the resin layer 44 and the adhesive layer 45. Moreover, the IC chip 11 is joined firmly to the wiring substrate 40 by the adhesive layer 45.

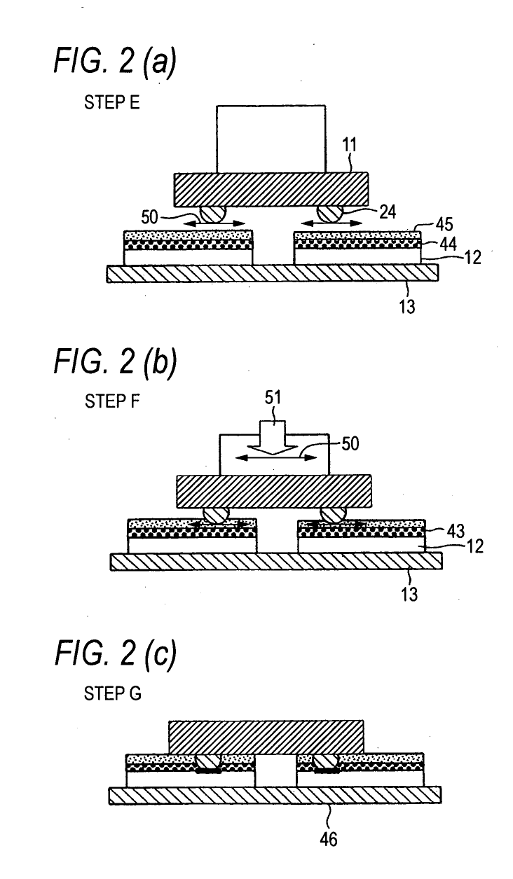

The featuring portions of the IC chip mounting method in this data carrier 10 is schematically described with reference to (a) to (c) of FIG. 2. FIG. 2(a) is a diagram schematically showing a step E of mounting the IC chip on the data carrier according to the embodiment; FIG. 2(b) is a diagram schematically showing a step F of mounting the IC chip on the data carrier according to this embodiment; and FIG. 2(c) is a diagram schematically showing a step G of mounting the IC chip on the data carrier according to this embodiment.

The data carrier manufacturing method according to this embodiment comprises: (the step E of) forming the resin layer 44 containing the dispersed insulating particles 43, on the surface of the conductor pattern 12 formed on the substrate 13; (the step F of) applying an ultrasonic wave 50 while pushing the electrodes (or bumps) 24 protruding from the IC chip 11 onto the surface of the thermoplastic adhesive layer 45 of the wiring substrate 40 having the resin film 44 coated on its surface with the thermoplastic adhesive layer 45, thereby to remove the resin layer 44 and the adhesive layer 45 as the insulating films on the conductor pattern 12; and (the step G of) performing the metal fusions 46 between the bumps 24 and the conductor pattern 12.

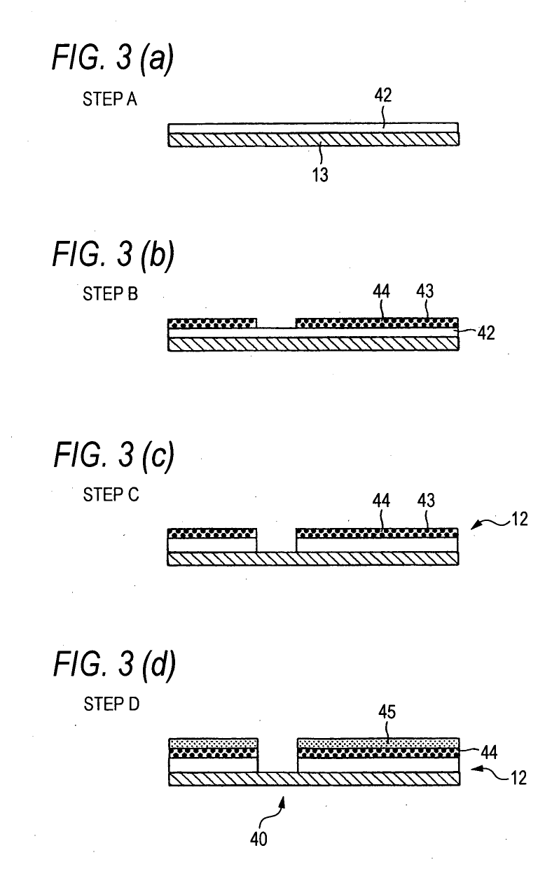

The individual steps of manufacturing the electric wave readable data carrier according to this embodiment are described in detail in the following with reference to FIG. 2 and FIG. 3.

At first, a step A to a step D or the characteristic pre-steps of the data carrier manufacturing method of the embodiment before the steps E to G are described with reference to (a) to (d) of FIG. 3. Here, (a), (b), (c) and (d) of FIG. 3 schematically show the step A, the step B, the step C and the step D, respectively.

(Step A)

As shown in FIG. 3(a), an Al-PET laminated base material is prepared at the first step. For example, a hard aluminum foil 42 having a thickness of 36 microns is laid through an urethane adhesive on one face of the substrate 13 made of a PET film having a thickness of 38 microns, and is adhered through a hot laminate under the conditions of 150° C. and a pressure of 5 Kg/cm². As a result, there is completed the Al-PET laminate which has the Al foil (42) adhered to the face of the PET film.

(Step B)

Next, on the surface of the hard aluminum foil 42 of the laminate, as shown in FIG. 3(b), there is formed the resin layer 44 which is made of the epoxy thermoset resin containing the dispersed SiO₂ particles (or the insulating particles) indicated by “solid circle” in FIG. 3(b). This resin layer 44 is formed into the conductor pattern 12 of the antenna, which is desired to have such an impedance as to match the impedance Zp at the time when the IC chip 11 is mounted on the circuit by the following method.

The resin layer 44 made of that epoxy thermoset resin is formed to have a thickness of about 4 to 6 microns: by applying such ink to the aforementioned Al-PET by the gravure printing method or the like that the epoxy resin and the SiO₂ particles 43 having the particle diameter of 3 to 4 microns in 30 wt. % of the epoxy resin are mixed with and dispersed in a solvent containing 30% of toluene, 6.1% of methyl ethyl ketone and 12% of butyl cellosolve; and by drying the ink at a temperature of 130° C. to 200° C. for about 20 seconds to 1 minute.

Here, the resin layer 44 made of the epoxy resin thermoset resin is printed in the desired antenna pattern shape 12 so that it can be used in the following as an etching resist for forming the antenna pattern.

(Step C)

As shown in FIG. 3(c), the Al foil portion is removed by the etching method known in the related art from the resin layer 44, which has been formed at the aforementioned step B in the conductor pattern shape to function as the etching resist. Specifically for this etching treatment, the unnecessary Al is removed by using NaOH (120g/litter) is used as the etching liquid under the condition of 50° C.

As a result, the conductor pattern of the hard Al foil 12 appears on the surface of the intermediate product of the wiring substrate obtained at this etching step. Moreover, the surface of this conductor pattern 12 is covered in its entirety with the resin layer 44, which is made of the epoxy thermoset resin used as the etching resist pattern (or the etching mask). In other words, at least the surface of the electrode area (i.e., the area to be connected with the bumps of the later-described IC chip (i.e., the semiconductor bare chip) 11) of that conductor pattern 12 is covered with the resin layer 44 made of the thermoset resin. Here, the coating thickness of the resin layer 44 of the thermoset resin can be adjusted according to the bump size or shape of the IC chip mounted.

(Step D)

Finally at this step, as shown in FIG. 3(d), the adhesive layer 45 made of the thermoplastic resin as the adhesive layer is formed all over the surface of the resin layer 44 made of the thermoset resin as the etching resist pattern. The wiring substrate 40 having the IC chip mounting substrate structure to be used in this embodiment is completed by applying the adhesive layer 45 of 4 to 6 microns and of the polyolefin thermoplastic resin to melt at a temperature of about 90° C. to 100° C. by a method such as the gravure printing method, to the entire face of the wiring substrate.

In short, the resin layer 44 of the thermoset resin is covered all over its surface with the adhesive layer 45 made of the thermoplastic resin. This results in the completion of the wiring substrate (i.e., the flip chip connecting wiring substrate) 40 having the IC chip mounting substrate structure. Here, the application thickness of this adhesive layer 45 made of the thermoplastic resin can be adjusted according to the bump size or shape of the IC chip to be mounted.

Next, the characteristic steps of the manufacturing method of this embodiment for mounting the IC chip at one end on the wiring substrate 40 prepared at the foregoing steps are described in detail with reference to the diagrams of (a) to (c) of FIG. 2.

(Step E)

At this step, as shown in FIG. 2(a), the IC chip 11 is mounted on the wiring substrate 40 while applying an ultrasonic wave thereto. At this step, the bumps 24 of the IC chip 11 is pushed onto the adhesive layer 45 made of the thermoplastic resin while applying the ultrasonic wave 50 thereto, thereby to bring the bumps 24 to the surface of the resin layer 44 of the thermoset resin while expelling the adhesive layer 45.

Specifically, the IC chip 11 is made to have the shape, in which the connecting bumps 24 are protruded from the bottom face of the bottom face of the IC chip 11. The IC chip 11 is pushed under the loading pressure of 0.2 Kg/mm² onto the adhesive layer 45 of the thermoplastic resin while the ultrasonic vibrations 50 of 63 KHz is being applied to the bumps 24 protruded from the bottom portion of the IC chip 11. At this time, the adhesive layer 45 is easily removed from the positions of the leading ends of the bumps by the ultrasonic vibrations of the bumps 24 so that the bumps 24 reach the surface of the resin layer 44 made of the thermoset resin containing the SiO₂ particles (or the insulating particles) dispersed therein.

In this example, the IC chip 11 has a thickness of 150 microns and is made as the so-called “surface-mount type parts”, in which the bumps 24 or the connecting metal terminals are protruded from the bottom face. Moreover, the bumps 24 are gold-plated gold terminals having a height of 14 microns and a width of 80 microns (i.e., 80×80 microns).

At this step, moreover, while the adhesive layer 45 of the thermoplastic resin being heated and softened, the bumps 24 of the IC chip 11 may also pushed onto the adhesive layer 45 in the molten state while the ultrasonic wave being applied thereto, so that the molten adhesive layer 45 may be expelled to bring the bumps 24 to the surface of the resin layer 44 of the thermoset resin. In the case of this step, the bumps 24 can reach the surface of the resin 44 while removing the adhesive layer 45 more reliably.

Here, the phrase of “being heated and softened” means that the concept containing both the state, in which the thermoplastic resin film is heated and softened to an extent, and the state, in which the same is heated and molted. Moreover, the “thermoplastic resin”, as termed herein, is preferred to have satisfactory properties as the adhesive.

(Step F)

At this step, as shown in FIG. 2(b), the bumps 24 are pushed (at 51) onto the resin layer 44 while continuously applying the ultrasonic wave 50 to the bumps 24, so that the resin layer 44 is expelled while bringing the SiO₂ particles 43 out of the inside of the resin layer 44 thereby to bring the bumps 24 and the electrode areas 46 in the conductor pattern 12 into contact with each other. Specifically, the bumps 24 are pushed (at 51) onto the resin layer 44 of the thermoset resin while applying the ultrasonic vibrations 50 to the bumps 24. Then, the SiO₂ particles (or the insulating particles) 43 in the resin layer 44 are scraped out of the inside of the resin layer 44 by the leading ends of the bumps 24 so that pores are formed in the resin layer 44. The bumps 24 pass through the pores thereby to reach the surface of the conductor pattern 12 of aluminum.

At this step, more specifically, the bumps 24 are pushed (at 51) onto the resin layer 44 of the thermoset resin while applying the ultrasonic vibrations 50 to the bumps 24. Then, the SiO₂ particles 43, as indicated by the “solid circles” in FIG. 2(b), are scraped out (or released) from the inside of the resin layer 44 by the bumps 24 so that the pores are formed in the resin layer 44. Here, it seems that the SiO₂ particles 43 released from the resin layer 44 are sucked (to dig) into the adhesive layer 45 of the thermoplastic resin. As a result of the formation of the pores, the resin layer 44 becomes brittle in resistance so that the bumps 24 can easily reach the surface (or its electrode areas) of the conductor pattern 12 of aluminum foil while expelling (or partially removing) the resin layer 44 of the thermoset resin.

(Step G)

At this step, the ultrasonic wave is further continuously applied while the bumps 24 and the surface (or its electrode areas) of the conductor pattern 12 of aluminum foil contacting with each other, thereby to join the bumps 24 and the electrode areas ultrasonically. In short, after the bumps 24 reached the surface (or its electrode areas) of the conductor pattern 12 of the aluminum foil at the aforementioned step F, the oxide layer or the like on the surface of the conductor pattern 12 of the aluminum foil is also mechanically removed by the ultrasonic vibrations of the bumps 24. As a result, the bumps 24 and the electrode areas come into contact.

Specifically, the insulating layer such as the oxide layer exists on the surface of the aluminum conductor pattern 12, too, and is also mechanically removed by the ultrasonic vibrations thereby to establish the metallic contact (between the gold terminals of the bumps 24 and the aluminum of the conductor pattern 12). When the ultrasonic vibrations are applied in this state, the two metals are molten by the frictional heat thereby to form the metal fusion portions 46.

The foregoing steps E to G for mounting the IC chip while applying the ultrasonic wave are completed, after the IC chip 11 was arranged at a predetermined position, by applying the ultrasonic vibrations of a frequency of 63 KHz for about 1.5 seconds, for example, under a loading pressure of 0.2 Kg/mm². Thus, the semiconductor chip can be mounted for a remarkably short time period.

When the ultrasonic wave 50 applied to the IC chip 11 is removed after the aforementioned steps, the adhesive layer 45 of the thermoplastic resin molten locally the ultrasonic wave sets again to adhere the IC chip 11 and the wiring substrate 40 thereby to complete the electric wave readable data carrier 10 according to this embodiment.

Here in case the adhesive layer 45 of the thermoplastic resin is molten in advance, the adhesive layer 45 of the molten thermoplastic resin can be forcibly cooled to set again thereby to adhere the body of the IC chip 11 and the wiring substrate 40. In other words, the adhesive layer 45 of the thermoplastic resin in the molten state between the bottom face of the IC chip 11 and the wiring substrate 40 is cooled and solidified to adhere and fix the IC chip 11 and the wiring substrate 40 firmly.

The structure of the data carrier 10 thus completed through the aforementioned steps is shown in section in FIG. 1. According to the method for manufacturing this data carrier 10, there are obtained the advantages: (1) a reliable electric conduction is achieved because the junction between the bumps 24 and the electrode areas is the diffused one by the ultrasonic wave; (2) a moisture resistance is achieved because the junction between the bumps 24 and the electrode areas is resin-encpsulated; (3) a mechanical mounting strength against the tension or the like is high because the IC chip 11 and the wiring substrate 40 are adhered when the thermoplastic resin film 45 sets; (4) the electric conduction and the mechanical junction can be simultaneously performed for a short time period; (5) the manufacturing cost is drastically low because neither any special encapsulating or adhering step nor any special adhesive material is needed; and (6) the substrate surface does not become more sticky than necessary at the heating time, because the thermoplastic resin film does not exists in the portions, in which the substrate surface is exposed.

In addition, (7) the situation that the IC chip 11 and the conductor pattern 12 of the aluminum foil may contact is prevented by the presence of the thermoset resin film 44 even if a hot temperature and a high-pressure load are applied to the IC chip mounting portion, because the resin layer 44 made of the thermoset resin which will not melt at a high temperature (e.g., within a range of at least 150° C. to 250° C. in this example) is interposed between the IC chip 11 and the conductor pattern 12 of the aluminum foil. It is, therefore, possible to realize the reliable data carrier 10, which has no fear of such short-circuit.

In addition, (8) the step of partial removing the thermoset resin film 44 for causing the bumps 24 to dig can be exemplified by a simple step of applying the ultrasonic vibrations to the bumps 24 thereby to push them onto the thermoset resin film 44, because the thermoset resin film 44 to be formed when the aforementioned data carrier 10 is manufactured contains the dispersed SiO₂ particles 43. If there is assumed the case, in which the insulating cover (or the insulating layer) containing none of the insulating particles such as the SiO₂ particles 43 between the adhesive layer 45 made of the thermoplastic resin and the conductor pattern 12 of the aluminum foil so as to prevent the aforementioned short-circuit, for example, the insulating layer cannot be easily removed only by the ultrasonic -vibrations of the bumps. 24. According to this embodiment, on the contrary, the insulating particles 43 (or the SiO₂ particles 43) are brought out of the thermoset resin film 44 by the ultrasonic vibrations of the bumps 24, as described hereinbefore, so that the pores are formed in the thermoset resin layer 44 thereby to make the resin layer 44 brittle in resistance. As a result, the bumps 24 can dig easily and for a short time period (of about 1 second) into the thermoset resin layer 44 thereby to bring their leading end portions to the aluminum foil conductor pattern 12 (or the electrode areas).

Moreover, no conductive particle exists between the IC chip 11 and the conductor pattern 12 so that the formation of the condenser component inbetween can be restricted to a small value. Moreover, the electrodes (or the bumps) 24. of the IC chip 11 and the conductor pattern 12 are connected by the metal melt thereby to make the highly reliable IC chip mount which has a highly reliable electric connection and a high mechanical strength. Moreover, the mounting time by the ultrasonic wave is about 2 seconds so that the high productivity can lower the manufacturing cost. In addition, any extreme area reduction of the circuit pattern just below the IC chip 11 for suppressing the formation of the condenser component is not needed to provide advantages that a highly precise alignment is needed and that the mounted state of the IC chip 11 is stabilized.

The present data carrier 10 can be electromagnetically read as an flight tag, a physical distribution label or an unattended wicket pass. Here, the impedance Zp obtained after the IC chip 11 was mounted n the data carrier 10 according to this embodiment is 3-j70 (Ω).

In the aforementioned embodiment, moreover, there was investigated the injection failure percentage of the semiconductor chip due to the diameter of the SiO₂ particles 43 dispersed and contained in the thermoset resin film 44. The injunction failure was at 50% in case the SiO₂ particles 43 had a diameter of 1 to 2 microns (i.e., about 30% of the thickness (i.e., 4 to 6 microns) of the thermoset resin film 44). In case the SiO₂ particles 43 had a diameter of 3 to 4 microns (i.e., 70% or more of the thickness (i.e., 4 to 6 microns) of the thickness of the thermoset resin film 44), on the other hand, no occurrence of the junction failure was found. It is, therefore, found preferable that the particle diameter of SiO₂ was 70% or more of the thickness of the thermoset resin film 44.

In this embodiment, moreover, the PET film was used as the resin base material constructing the laminate material but can also be replaced by a polyimide film.

For forming the thermoset resin film 44, moreover, this embodiment used the ink which had been prepared by mixing 30 wt. % of SiO₂ particles 43 with 100 wt. % of the epoxy resin. If the mixing percentage of the epoxy resin and the SiO₂ particles in the ink is within a range of 10 to 30 wt. % with respect to 100 wt. % of the epoxy resin, it has been confirmed according to the founding obtained as a result of our keen investigations that the ultrasonic mounting of the aforementioned semiconductor bare chip is satisfactorily executed:

In the embodiment, moreover, the SiO₂ (silica) was used as the material for the insulating particles to be dispersed and contained in the thermoset resin film 44 but can also be exemplified by Al₂O₃ (alumina) or tetrafluoroethylene. In addition, it may be necessary for the application that the wiring substrate 40 is cut. In this case, the cutting blade may have its lifetime shortened, if the thermoset resin film 44 is made to contain hard particles of oxides such as the SiO₂ particles or the Al₂O₃ particles. In this case, it is preferable to use softer tetrafluoroethylene.

In the embodiment, moreover, the insulating layer between the thermoplastic resin film 45 and the aluminum foil conductor pattern 12 is exemplified by the thermoset resin film 44. However, the insulating layer can also be a thermoplastic resin layer having a far higher re-softening temperature (so that it can hold the hardened state even under the situations where the thermoplastic resin film 45 is molted because a high temperature needed for the working treatment such as the stacking press or the injection molding was applied) than that of the thermoplastic resin film 45. In this case, too, it goes without saying that the SiO₂ particles (or the insulating particles) are contained in the insulating layer. Here, the wiring substrate of this case can be generalized as the flip chip connecting semiconductor chip: which includes the conductor pattern, the first thermoplastic resin film covering the electrode areas over the conductor pattern and containing the dispersed insulating particles, and the second thermoplastic resin film covering the first thermoplastic resin film; and which has a sufficiently higher re-softening temperature of the first thermoplastic resin film than that of the second thermoplastic resin film. On the other hand, the wiring substrate 40 exemplified in this embodiment can be generalized as the flip chip connecting wiring substrate which includes the conductor pattern 12, the thermoset resin film 44 covering the electrode areas over the conductor pattern 12 and containing the dispersed insulating particles, and the thermoplastic resin film 45 covering the thermoset resin film. According to these wiring substrates, it is possible to manufacture the highly reliable data carrier which can mount the IC chip 11 with the bumps 24 easily at a low cost thereby to have a high junction strength and eliminate any short-circuit even when loads of a high temperature and a high pressure are applied.

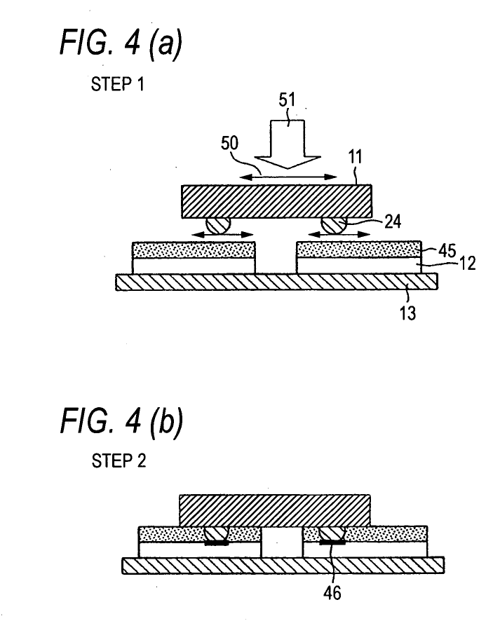

Moreover, FIG. 4 shows the steps of mounting the IC chip of the case, in which the thermoset resin layer 44 having the dispersed insulating particles is absent. This mounting step is basically identical to the aforementioned one but is different only in the absence of the step of eliminating the thermoset resin layer 44 having the dispersed insulating particles by the bumps 24. Specifically, the IC chip 11 is mounted by: the step of pushing (51) the bumps 24 of the IC chip 11 onto the adhesive layer 45 made of the thermoset resin, while applying the ultrasonic wave 50 thereto, thereby to exclude the adhesive layer 45 to bring the bumps 24 and the conductor pattern 12 (i.e., the electrode areas) into contact; the step of further applying the ultrasonic wave 50 continuously while the bumps 24 and the conductor pattern 12 (or the electrode areas) contacting with each other, to join the bumps 24 and the conductor pattern 12 (or the electrode areas) ultrasonically; and the step of cooling to solidify the adhesive layer 45 made of the thermoplastic resin thereby to adhere the IC chip 11 to the wiring substrate 40.

As a result, the time period necessary for the mounting is as short as the aforementioned one, and the resin layer 44 containing the insulating particles 43 of a high dielectric constant is absent between the IC chip 11 and the conductor pattern 12. This raises an advantage that the condenser capacity can be reduced. However, the adhesive layer 45 made of the thermoplastic resin is not present as the insulating layer of the IC chip 11 and the conductor pattern 12 (or the electrode areas). This cannot deny the fear of causing the problem that the electric insulation between the IC chip 11 and the conductor pattern 12 (or the electrode areas) cannot be held under a high temperature load.

### Embodiment 2

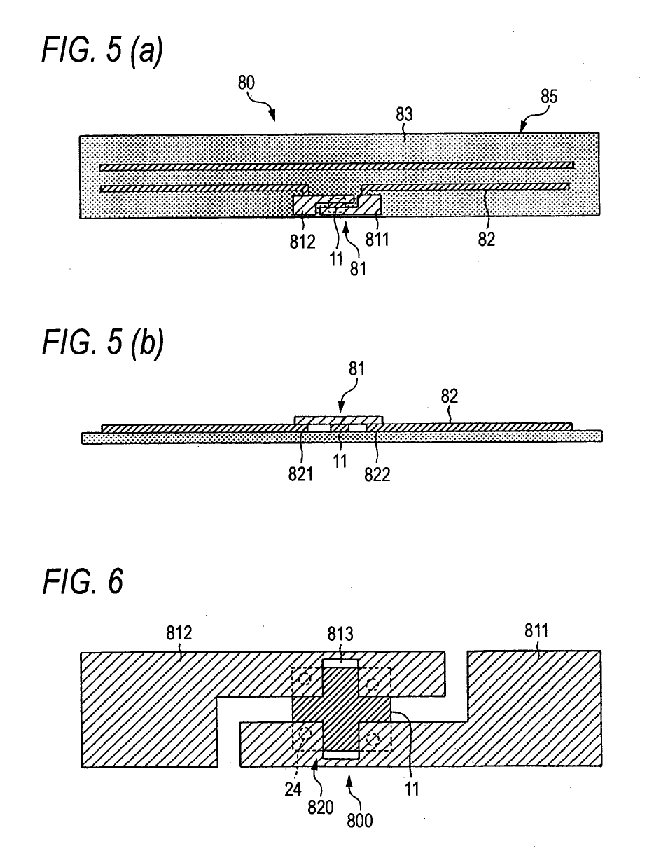

Another embodiment of the electric wave readable data carrier according to the invention is described with reference to FIG. 5 and FIG. 6. Here, for conveniences of explanations, the description of the members having the same functions as those of the members described in connection with Embodiment 1 is omitted by designating them by the common reference numerals. This embodiment is described on the points different from those of Embodiment 1.

A data carrier 80 according to this embodiment has a structure, in which an antenna pattern 82 made of copper of 9 microns is formed on one face of a substrate 83 made of a film resin base material of PET (polyethylene terephthalate) of 38 microns, and in which a substrate module (or an electronic component module) 81 having the IC chip 11 mounted thereon is electrically connected with one terminal of the antenna pattern 82 through connecting portions 811 and 812 of the antenna. Here, the data carrier 80 is configured as the electric wave readable data carrier using electric waves of 850 MHz especially electric waves of the UHF band of 850 MHz to 960 MHz as the communication frequency. Specifically, the data carrier 80 is configured by integrating a data carrier body 85, in which the antenna for forming conductor (metal) pattern 82 is held on the film-shaped resin base material (or the insulating base material), and the electronic component module 81, in which the semiconductor bare chip for forming a transmitter/receiver circuit and a memory is mounted on the aluminum foil wiring pattern on the surface of the film-shaped resin base material. This data carrier 80 can be electromagnetically read as the flight tag, the physical distribution label or the unattended wicket pass.

Here is described a method for manufacturing the electric wave readable data carrier 80 according to this embodiment.

(1) First of all, there is prepared the data carrier body (or the antenna substrate) 85, in which the conductor pattern 82 for forming the antenna is formed. The data carrier body 85 in this embodiment is formed at steps similar to those of Embodiment by substituting the copper foil 82 for the hard aluminum foil 42 in Embodiment 1 and by forming the thermoset resin layer, which is made of the epoxy resin excepting the insulating particles (i.e., SiO₂ particles) 43 from the thermoset resin layer 44 in Embodiment 1, on the copper foil 82.

Specifically, a Cu-PET laminated base material is prepared for the first time. For example, a copper film having a thickness of 10 microns is laid through an urethane adhesive on one side of the substrate 83 made of a PET film having a thickness of 25 microns, and is stacked and adhered through a hot laminate under the conditions of 150° C. and a pressure of 5 Kg/cm². As a result, the Cu-PET laminate having the copper foil adhered to the surface of the substrate 83 of the PET film is completed.

Next, an antenna-shaped etching resist pattern is formed on the surface of the copper foil of the Cu-PET laminate base material. By using the offset printing method, more specifically, insulating etching resist ink is printed in such a shape on the copper foil as to acquire the antenna characteristics necessary for utilizing the electric waves of the UHF band. The resist ink used at this time is of the type, in which it is set with heat or activation energy. The activation energy beam used is an ultraviolet ray or an electron beam. A photopolymerizer is introduced into the resist ink, in case the ultraviolet ray is used.

Next, a conductive etching resist pattern of a necessary electrode shape is formed with conductive ink at such positions on the surface of the copper foil of the Cu-PET laminate base material as to make electrically conductive connections with the electrodes of the electronic component module 81. This resist pattern is formed by an offset printing method like the aforementioned one, and the resist ink used is a thermosetting conductive adhesive which sets with a heat treatment of 120° C. for about 20 minutes. Here, the printing of the conductive ink at this step may be exemplified by the generally executed screen printing method, and the ink material may be prepared by introducing a photopolymerizer into the mixture of Ag particles and a thermoplastic adhesive or by using solder paste or the like, for example.

Next, the copper foil portion exposed from the etching resist pattern is removed by the conventional etching method, thereby to form the conductor pattern (at 82 in FIG. 5) for the antenna. At this etching treatment, an etching liquid of FeCl2 (of 120 g/litter) is used at 50° C. to remove the copper foil. Generally, the electronic components cannot be mounted on the circuit, i.e., on the conductor pattern for forming the antenna, unless the etching resist formed at the foregoing step is removed. In the invention, however, the conductive resist pattern is present, as described in connection with the foregoing step, so that the etching resist need not be removed by mounting the electronic components at that position. In other words, the step of peeling the etching resist can be omitted according to the invention. Another advantage is that the etching resist formed with the insulating ink also functions as the insulation protecting layer for the surface of the circuit pattern of the copper foil.

Finally, in this embodiment, a through hole is pressed for inserting the (potting portion) of the later-described ridge of the electronic component module 81. Thus, there is completed the data carrier body 85, on which the conductor pattern 82 for the antenna is held on one side of the substrate 83 made of the PET film.

(2) Next, there is prepared the electronic component module 81 having the IC chip 11 mounted thereon. This electronic component module 81 is formed through the same steps as those of Embodiment 1, excepting that the circuit pattern shape takes the shape shown in FIG. 5.

Specifically, the Al-PET laminate base material is manufactured at first as the base material for the film-shaped wiring substrate. This Al-PET laminate base material is manufactured, for example, through steps of stacking a hard aluminum foil having a thickness of 35 microns on one face of the PET film having a thickness of 25 microns through an urethane adhesive, and stacking and adhering the laminate through a hot laminate under the conditions of 150° C. and a pressure of 5 Kg/cm².

On the surface of the hard aluminum foil of the Al-PET laminate base material, there is then formed the first resist layer for forming the etching resist pattern of a desired conductor (wiring) pattern shape. In this example, the first resist layer is formed as the epoxy thermoset resin film containing SiO₂ particles (or insulating particles) dispersed therein. Specifically, this epoxy thermoset resin film (i.e., the first resist layer) is formed to have a thickness of about 4 to 6 microns: by applying such ink to the surface of the aforementioned Al-PET laminate base material by the gravure printing method or the like as is prepared by mixing 100 wt. % of the epoxy resin and 30 wt. % of the SiO₂ particles 43 having the particle diameter of 3 to 4 microns of the epoxy resin are mixed with a solvent containing 30% of toluene, 6.1% of methyl ethyl ketone and 12% of butyl cellosolve; and by drying the ink at a temperature of 130° C. to 200° C. for about 20 seconds to 60 seconds.

Subsequently, the thermoplastic resin film is formed as the second resist layer (also acting as the adhesive layer) is formed all over the surface of the thermoplastic resin film as the first resist layer. This thermoplastic resin film is formed by applying an olefin thermoplastic resin adhesive of a thickness of about 4 to 6 microns to melt at a temperature of about 90° C. to 100° C., by the gravure printing method or the like, to the surface of the thermoset resin film. In short, the surface of the thermoset resin film is covered all over with the thermoset resin film.

Next, the etching resist pattern of the desired conductor pattern shape, which is formed to have the thermoset resin film and the thermoplastic resin film, is formed through the aforementioned steps on the hard aluminum foil.

Then, the conductor pattern of the hard aluminum foil is formed by eliminating the aluminum foil portion exposed from the etching resist pattern, by the well-known etching treatment of the related art. For forming the conductor pattern, the aluminum foil portion exposed from the etching resist pattern is exposed to an etching liquid of NaOH (120 g/litter), for example, under the condition of a temperature of 50° C. As a result, there is obtained the wiring substrate, in which the wiring pattern of the hard aluminum foil is exposed to the surface.

Subsequently, the IC chip 11 is mounted on the wiring substrate while applying the ultrasonic wave thereto. This method includes: the step of pushing the bumps of the IC chip 11 onto the thermoset resin film while applying the ultrasonic wave thereto, to expel the thermoset resin film thereby to bring the bumps to the surface of the thermoset resin film; the step of pushing the bumps onto the thermoset resin film while further applying the ultrasonic wave continuously to the bumps, to expel the thermoset resin film while releasing the SiO₂ particles from the inside of the thermoset resin film thereby to bring the bumps and the electrode areas on the hard aluminum foil into contact; and the step of further applying the ultrasonic wave continuously while the bumps and electrode areas contacting with each other, thereby to join the bumps and the electrode areas ultrasonically. The details are similar to those of Embodiment 1 so that their description is omitted.

Finally, by eliminating the ultrasonic wave applied to the wiring substrate, the partially molten thermoset resin film is reset by the natural cooling or the forced cooling, thereby to adhere the IC chip body and the wiring substrate. Specifically, the thermoset resin film filled in the molten state between the bottom face of the IC chip and the wiring substrate is cooled and solidified to adhere and fix the IC chip and the wiring substrate firmly. After this, the IC chip 11 is resin-capsulated, if necessary, by the well-known method to form the potting portion.

(3) Next, the electrodes (or the terminal portions) of the electronic component module 81 are electrically connected, at the positions of the terminals 821 and 822 of the conductor pattern 82 forming the aforementioned antenna, with the conductor pattern forming the antenna.

At this time, these electrode connections can be carried out by the manufacturing method disclosed in JP-A-2001-156110. Specifically, the terminal portions 811 and 812 of the electronic component module 81 are arranged at positions to confront the connecting pad portions 821 and 822 at the terminal portions of the conductor pattern 82 forming the antenna. Next, the terminal portions 811 and 812 of the electronic component module 81 are joined by applying the ultrasonic vibrations of a load pressure of 0.2 Kg/mm² and a frequency of 40 KHz to just above the terminal portions 811 and 812 for about 0.5 seconds. Here, the connections at this step may be executed by arranging anisotropic conductive paste between the connecting pad portions 821 and 822 at the terminal portions of the conductor pattern 82 forming the antenna and the circuit of the electronic component module 81.

In this embodiment, the IC chip 11 is not directly mounted like Embodiment 1 on the conductor pattern forming a large-sized antenna but has an advantage to improve the mounting precision of the IC chip 11 in addition to the advantages described in Embodiment 1, because it is mounted on the wiring substrate of a small-sized electronic component module.

On the other hand, FIG. 6 is a diagram schematically showing a circuit pattern of a wiring substrate of an electronic component module in this embodiment. From a wiring substrate 800 to confront the IC chip 11, as shown in FIG. 6, there are removed areas 813 other than an area 820, in which the bumps 24 of the IC chip 11 and the wiring substrate contact with each other. In the wiring substrate 800 to confront the IC chip 11, specifically, the circuit portion just below the IC chip 11 is partially removed so that the area of the wiring substrate to confront the IC chip 11 can be reduced. As a result, it is possible to reduce the impedance Zp after the IC chip 11 was mounted on the data carrier body. Here, the Zp according to this method is 5-j120 (Ω). It is found that the condenser capacity between the IC chip 11 and the conductor pattern forming the antenna can be made smaller than that of the aforementioned data carrier of Embodiment 1.

### Embodiment 3

In the aforementioned Embodiment 2, as shown in FIG. 6, the circuit portion just below the IC chip 11 in the wiring substrate 800 to confront the IC chip 11 is partially removed to reduce the impedance Zp after the IC chip 11 was mounted on the data carrier body. This results in the reduction of the contact area between the IC chip 11 and the circuit portion.

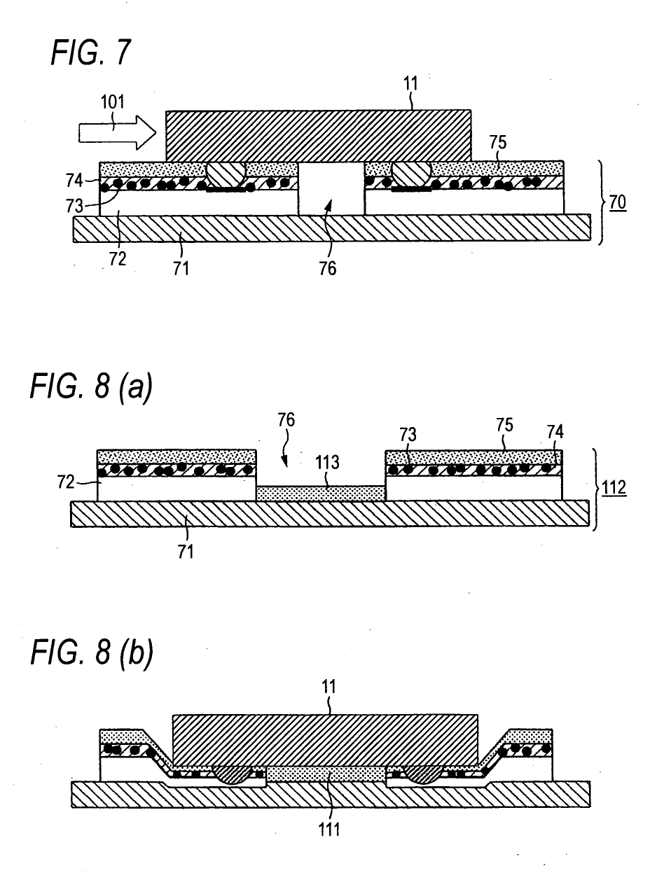

Specifically, a circuit portion 76 just below the IC chip 11 in a wiring substrate 70 to confront the IC chip 11 is partially removed, as shown in FIG. 7. Therefore, the junction strength (as will be called the “shared strength”) 101 between the IC chip 11 and the wiring substrate 70 is reduced to raise a problem that the mounting reliability of the IC chip 11 is lowered.

This embodiment provides an IC chip mounting method for solving that problem. Specifically, the electric wave readable data carrier manufacturing method provided comprises: the step of forming, before executing the step of pushing the bumps 24 of the IC chip 11 while applying the ultrasonic wave thereto, the adhesive layer (e.g., the thermoplastic adhesive layer) is formed, excepting the area in which the bumps 24 of the IC chip 11 and the wiring substrate contact with each other, in an area of the wiring substrate to confront the IC chip 11; and the step of pushing a load to compress and deform a portion of the wiring substrate in that step of pushing the bumps of the semiconductor bare chip while applying the ultrasonic wave thereto. The manufacturing method according to this embodiment is described with reference to FIG. 8. Here, FIG. 8(a) schematically shows the step A in this embodiment, and FIG. 8(b) schematically shows the step B in this embodiment.

(Step A)

At first, there is prepared a wiring substrate 112 for mounting the IC chip 11. The wiring substrate 112 to be used in this embodiment is formed through substantially the same steps as the steps A to D of Embodiment 1 or through those of Embodiment 2.

Specifically-in the wiring substrate 112, on one face of a substrate 71 made of PET film having a thickness of 38 microns, there is formed a wiring pattern 72 which is made of a hard aluminum foil 42 formed in a wiring pattern shape. On the surface of the wiring pattern 72, there is formed a resin layer 74 which is made of an epoxy thermoset resin containing SiO₂ particles (or insulating particles) 73 dispersed therein. An adhesive layer 75 made of a thermoplastic resin is formed to cover the whole face of the resin layer 74.

In this embodiment, moreover, at a removed circuit portion 76 just below the IC chip in the wiring substrate 70 to confront the IC chip 11, a thermoset adhesive layer 113 of 4 to 6 microns is reliably applied to the surface of the substrate 71 just below the IC chip 11 between the wiring patterns 72.

Next, the IC chip 11 is mounted on the wiring substrate 112. At this time, the mounting of the IC chip 11 is carried out by a method like that of Embodiment 1 and Embodiment 2. Nevertheless, the loading pressure at the time of applying the ultrasonic wave at the step E in Embodiment 1 is applied under the pressure condition to reach a loading pressure as high as 0.7 Kg/mm² finally.

By applying the ultrasonic wave under this high loading pressure, the wiring pattern 72 in the wiring substrate 112 is compressed and deformed. As a result, the bottom face of the IC chip 11 reaches the surface of the thermoplastic adhesive layer 113 to provide a package of the IC chip, which is firmly joined in a junction interface 111.

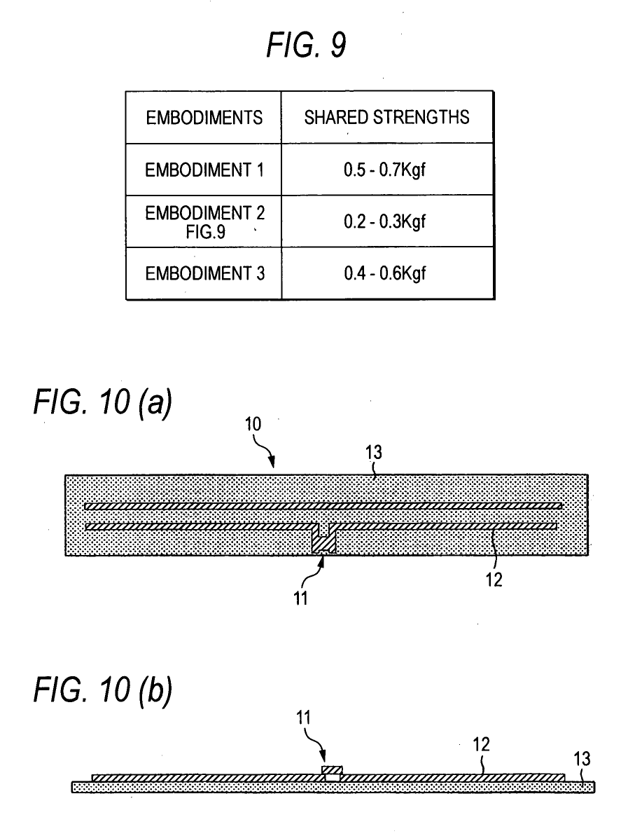

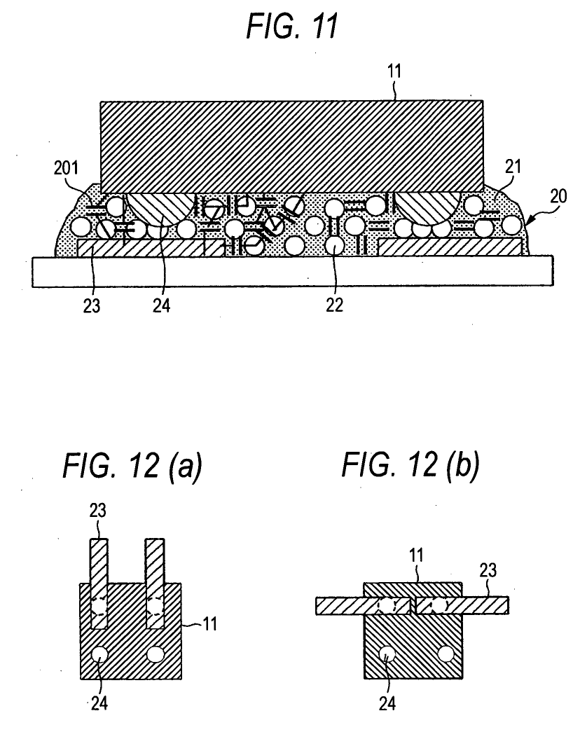

FIG. 9 presents the compared values of shared strengths in the package of Embodiment 1, the package of FIG. 6 in Embodiment 2 and the package of this embodiment. It is understood from FIG. 9 that the shared strength degraded in the case of the package of Embodiment 2, as shown in FIG. 6, can be improved in the package manufactured by the method of this embodiment.

The invention also contains an electric wave readable data carrier manufacturing method using a UHF band as a communication frequency, that is, a method for manufacturing an electric wave readable data carrier having a semiconductor chip mounted on a data carrier body holding a metal pattern forming an antenna in a film-shaped resin base material, wherein the method for mounting a semiconductor chip on the substrate comprises: the step of pushing bumps of the semiconductor chip onto the thermoplastic resin film while applying an ultrasonic wave thereto, thereby to expel the thermoplastic resin film to bring the bumps and the electrode areas into contact; the step of further applying the ultrasonic wave continuously while the bumps and the electrode areas contacting, thereby to join the bumps and the electrode areas ultrasonically; and the step of cooling and solidifying the thermoplastic resin film thereby to adhere the semiconductor chip body to the substrate.

The invention further contains an electric wave readable data carrier manufacturing method using a UHF band as a communication frequency, that is, a method for manufacturing an electric wave readable data carrier having a semiconductor chip mounted on a data carrier body holding a metal pattern forming an antenna in a film-shaped resin base material, wherein the method for mounting a semiconductor chip on the substrate comprises: the step of pushing bumps of the semiconductor chip onto the thermoplastic resin film while applying an ultrasonic wave thereto, thereby to expel the thermoplastic resin film to bring the bumps and the electrode areas into contact; the step of further applying the ultrasonic wave continuously while the bumps and the electrode areas contacting, thereby to join the bumps and the electrode areas ultrasonically; and the step of cooling and solidifying the thermoplastic resin film thereby to adhere the semiconductor chip body to the substrate, and wherein a resin film containing insulating particles having a dielectric constant of 3 or less dispersed therein is disposed between the thermoplastic resin film and the electrode areas.

The invention further contains an electric wave readable data carrier manufacturing method using a UHF band -as a communication frequency, that is, a method for manufacturing an electric wave readable data carrier having a semiconductor chip mounted on a data carrier body holding a metal pattern forming an antenna in a film-shaped resin base material, and a semiconductor chip for forming a transmitter/receptor circuit, a memory and so on in the wiring pattern on the surface of the film-shaped resin base material, wherein the method for manufacturing an electronic component module mounting a semiconductor chip forming the transmitter/receptor circuit, the memory and so on in the wiring pattern of the film-shaped resin base material surface comprises: the step of pushing bumps of the semiconductor chip onto the thermoplastic resin film while applying an ultrasonic wave thereto, thereby to expel the thermoplastic resin film to bring the bumps and the electrode areas into contact; the step of further applying the ultrasonic wave continuously while the bumps and the electrode areas contacting, thereby to join the bumps and the electrode areas ultrasonically; and the step of cooling and solidifying the thermoplastic resin film thereby to adhere the semiconductor chip body to the substrate.

The invention further contains an electric wave readable data carrier manufacturing method using a UHF band as a communication frequency, that is, a method for manufacturing an electric wave readable data carrier having a semiconductor chip mounted on a data carrier body holding a metal pattern forming an antenna in a film-shaped resin base material, and a semiconductor chip for forming a transmitter/receptor circuit, a memory and so on in the wiring pattern on the surface of the film-shaped resin base material, wherein the method for manufacturing an electronic component module mounting a semiconductor chip forming the transmitter/receptor circuit, the memory and so on in the wiring pattern of the film-shaped resin base material surface comprises: the step of pushing bumps of the semiconductor chip onto the thermoplastic resin film while applying an ultrasonic wave thereto, thereby to expel the thermoplastic resin film to bring the bumps and the electrode areas into contact; the step of further applying the ultrasonic wave continuously while the bumps and the electrode areas contacting, thereby to join the bumps and the electrode areas ultrasonically; and the step of cooling and solidifying the thermoplastic resin film thereby to adhere the semiconductor chip body to the substrate, and wherein a resin film containing insulating particles having a dielectric constant of 3 or less dispersed therein is disposed between the thermoplastic resin film and the electrode areas.

The invention should not be limited to the individual embodiments thus far described but could be modified in various manners within the scope defined by claims. The embodiments, as could be obtained by suitably combining the technical means disposed individually in the different embodiments, also belong to the technical range of the invention.

According to the invention, it is possible to provide an electromagnetic wave readable data carrier, which can massively produce an electromagnetic wave readable data carrier to function as the flight tag, the physical distribution label, the unattended wicket pass, and so on. Therefore, it can be said that the invention has a remarkably useful industrial application.

1. A method for manufacturing an electric wave readable data carrier having a semiconductor bare chip with a bump mounted on a substrate and using an electric wave of 850 MHz or higher as a communication frequency, wherein said substrate includes a conductor pattern for forming an antenna, a resin film containing insulating particles dispersed therein for covering an electrode area on said conductor pattern, and a thermoplastic resin film for covering the resin film containing said dispersed insulating particles, said method comprising steps of:
pushing the bump of the semiconductor bare chip onto said thermoplastic resin film while applying an ultrasonic wave thereto, thereby to expel said thermoplastic resin film to bring the bump to a surface of the resin film containing said dispersed insulating particles;
pushing the bump onto the resin film containing said dispersed insulating particles by further applying the ultrasonic wave continuously, thereby to expel said resin film while releasing said insulating particles from the inside of the resin film, to bring the bump and the electrode area into contact;
further applying the ultrasonic wave continuously while said bump and said electrode area contacting, thereby to join the bump and the electrode area ultrasonically; and
cooling and solidifying said thermoplastic resin film thereby to adhere the semiconductor bare chip to the substrate.

2. An electric wave readable data carrier manufacturing method according to claim 1,
wherein the insulating particles contained and dispersed in said resin film are insulating particles having a dielectric constant of 3 or less.

3. An electric wave readable data carrier manufacturing method according to claim 1,
wherein the insulating particles contained and dispersed in said resin film are silicon oxides or super-hydrophobic silicon oxides.

4. An electric wave readable data carrier manufacturing method according to claim 1,
wherein the insulating particles contained and dispersed in said resin film are tetrafluoroethylene.

5. An electric wave readable data carrier manufacturing method according to claim 1,
wherein a diameter of the insulating particles contained and dispersed in said resin film is 70% or more of a thickness of said resin film.

6. An electric wave readable data carrier manufacturing method according to claim 1,
wherein a content of the insulating particles contained and dispersed in said resin film is 10 wt. % to 30 wt. % of 100 wt. % of the resin.

7. An electric wave readable data carrier manufacturing method according to claim 1,
wherein the resin film containing the dispersed insulating particles is made of a thermoset resin.

8. An electric wave readable data carrier manufacturing method according to claim 1,
wherein the resin film containing the dispersed insulating particles is made of a thermoplastic resin having a higher re-softening temperature than that of a material of the thermoplastic resin film covering said resin film.

9. A substrate comprising:
a conductor pattern forming an antenna;
a resin film covering an electrode area on said conductor pattern and containing insulating particles dispersed therein; and
a thermoplastic resin film covering the resin film containing said dispersed insulating particles.

10. A substrate according to claim 9,
wherein the insulating particles contained and dispersed in said resin film are silicon oxides or super-hydrophobic silicon oxides.

11. A substrate according to claim 9,
wherein the insulating particles contained and dispersed in said resin film are tetrafluoroethylene.

12. A substrate according to claim 9,
wherein the insulating particles contained and dispersed in said resin film are particles having a diameter of 70% or more of a thickness of said resin film.

13. A substrate according to claim 9,
wherein a content of the insulating particles contained and dispersed in said resin film is from 10 wt. % to 30 wt. % of 100 wt. % of the resin.

14. A substrate according to claim 9,
wherein the resin film containing said dispersed insulating particles is made of a thermoset resin.

15. A substrate according to claim 9,
wherein the resin film containing said dispersed insulating particles is a thermoplastic resin having a higher re-softening temperature than that of a material of the thermoplastic resin film covering said resin film.

16. A substrate according to claim 9,
wherein the insulating particles contained and dispersed in said resin film are insulating particles having a dielectric constant of 3 or less.

17. A method for manufacturing an electric wave readable data carrier having a data carrier body and an electronic component module and using an electric wave of 850 MHz or higher as a communication frequency, said data carrier body including a conductor pattern forming an antenna formed on an insulating substrate, said electronic component module including a wiring substrate having a wiring pattern, a resin film containing insulating particles dispersed therein for covering an electrode area on said wiring pattern and a thermoplastic resin film covering the resin film containing said dispersed insulating particles, and a semiconductor bare chip with a bump, said method comprising steps of:
pushing the bump of the semiconductor bare chip onto said thermoplastic resin film while applying an ultrasonic wave thereto, thereby to expel said thermoplastic resin film to bring the bump to a surface of the resin film containing said dispersed insulating particles;
pushing said bump onto the resin film containing said dispersed insulating particles by further applying the ultrasonic wave continuously, thereby to expel said resin film while releasing said insulating particles from the inside of the resin film, to bring the bump and the electrode area into contact;
further applying the ultrasonic wave continuously while said bump and said electrode area contacting, thereby to join the bump and the electrode area ultrasonically; and
cooling and solidifying said thermoplastic resin film thereby to adhere the semiconductor bare chip body to said wiring substrate.

18. An electric wave readable data carrier manufacturing method according to claim 17,
wherein, in said electronic component module, the wiring substrate to confront said semiconductor bare chip is formed excepting areas other than an area where the bump of said semiconductor bare chip and said wiring substrate contact.

19. An electric wave readable data carrier manufacturing method according to claim 18, further comprising a step of:
before the step of pushing the bump of said semiconductor bare chip while applying the ultrasonic wave thereto, forming an adhesive layer in an area of the wiring substrate to confront said semiconductor bare chip excepting the area in which the bump of said semiconductor bare chip and the wiring substrate contact,
wherein the step of pushing the bump of said semiconductor bare chip while applying the ultrasonic wave thereto, includes a step of pushing with a load to compress and deform a portion of said wiring substrate.

20. An electric wave readable data carrier manufacturing method according to claim 19,
wherein a portion of the wiring substrate to be compressed and deformed is the wiring pattern.

21. An electronic component module comprising:
a wiring substrate having a wiring pattern, a resin film containing insulating particles dispersed therein for covering an electrode area on said wiring pattern and a thermoplastic resin film covering the resin film containing said dispersed insulating particles; and
a semiconductor bare chip having a bump,
wherein said semiconductor bare chip is mounted on said wiring substrate, and
wherein, in said electronic component module, the wiring substrate to confront said semiconductor bare chip is formed excepting areas other than an area where the bump of said semiconductor bare chip and said wiring substrate contact.
